(19) United States
(12) Patent Application Publication
(10) Pub. No.: US 2009/0014755 A1
(43) Pub. Date: Jan. 15, 2009

(54) DIRECT BOND SUBSTRATE OF IMPROVED BONDED INTERFACE HEAT RESISTANCE

(76) Inventor: Takashi Nakao, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/146,672

(22) Filed: Jun. 26, 2008

(30) Foreign Application Priority Data
Jun. 29, 2007 (JP) 2007-173243

(51) Int. Cl. H01L 21/18; H01L 27/092

(52) U.S. Cl. 257/190; 438/455; 257/E27.062; 257/E21.087

(57) ABSTRACT

A direct bond substrate formed by bonding semiconductor substrates together, a semiconductor device using the direct bond substrate and a manufacturing method thereof are disclosed. A nitride film, oxynitride film, carbide film or an oxide film containing carbon is provided on the bonded interface of the semiconductor substrates in the direct bond substrate.

### CROSS-REFERENCE TO RELATED APPLICATIONS

This application is based upon and claims the benefit of priority from prior Japanese Patent Application No. 2007-173243, filed Jun. 29, 2007, the entire contents of which are incorporated herein by reference.

### BACKGROUND OF THE INVENTION

1. Field of the Invention

This invention relates to a direct bond substrate formed by bonding semiconductor substrates together, a semiconductor device using the direct bond substrate and a manufacturing method thereof and, more particularly, to the improvement of heat resistance of a bonded interface.

2. Description of the Related Art

A semiconductor device using a direct bond substrate, for example, a substrate having a direct silicon bond (DSB) has a structure in which hybrid-orientation-technology can be used and which does not have a silicon-on-insulator (SOI) structure. The structure is disclosed in Jpn. Pat. Appln. KOKAI Publication No. 2005-136410, for example.

The DSB substrate does not have buried oxide (BOX) unlike the SOI substrate. Therefore, ideally, nothing other than silicon is provided on an interface on which silicon layers having different plane orientations (crystal orientations) are bonded together.

In a conventional manufacturing method of a general DSB substrate, like an SOI substrate formed by bond, the surface of a silicon substrate that has a plane orientation, for example, (110) different from a specified plane orientation, for example, (100) of the surface of a different silicon substrate is set to face the surface of the different silicon substrate and is bonded thereon. In this case, since a silicon substrate whose plane orientation is (100) (which is hereinafter referred to as a (100) silicon substrate) does not have BOX, the silicon surface thereof is directly adhered to the silicon surface of a silicon substrate whose plane orientation is (110) (which is hereinafter referred to as a (110) silicon substrate).

After this, a DSB substrate with a thin silicon film of the plane orientation (110) disposed thereon can be formed on the (100) silicon substrate used as a base body by separating the (110) silicon substrate while an upper layer of several ten nm to several hundred nm lying near the surface portion thereof is left behind.

Next, a process of manufacturing a semiconductor device having a HOT structure is explained by use of a substrate using DSB.

In the case of the above example, since the (100) silicon substrate is used as a base substrate acting as a ground layer, a region in which NFETs (N-channel FETs) are to be formed is opened and a region in which PFETs (P-channel FETs) are to be formed is left behind after the substrate surface is covered with an adequate mask member.

Then, ions of a IV group such as Si, Ge and ions of an inert gas such as Ar are ion-implanted into the region in which the NFETs are to be formed from above the resultant structure by using an ion-implantation apparatus. The ion-implantation process is performed with such energy and dose amount as to form a (110) silicon film on the substrate surface and part of the upper surface portion of the (100) silicon substrate that lies below the above silicon film into an amorphous form. Thus, a portion ranging from the surface of the above region to part of the upper surface of the (100) silicon substrate is formed into an amorphous form.

After this, the portion that is formed into the amorphous form by solid phase epitaxy (SPE) is re-crystallized by performing an annealing process at temperatures higher than or equal to 600° C. At this time, in order to acquire information of re-crystallization from the underlying (100) silicon substrate, a portion that is once formed into an amorphous form and re-crystallized has (100) plane orientation in a region up to the substrate surface.

By the above process, a HOT structure having different plane orientations, that is, (110) plane orientation in the PFET region and (100) plane orientation in the NFET region can be formed. By thus causing the regions in which the PFETs and NFETs are formed to have plane orientations suitable for the respective transistor characteristics, the carrier mobility of each transistor can be enhanced and the operation speed of an LSI can be enhanced by increasing a current flowing through each MOSFET.

However, damage caused by ion-implantation still remain on the interface that is recovered from the amorphous state in the NFET region and a region of crystal defects that is not sufficiently restored is present. In order to recover the region from the crystal defects, it is necessary to perform a heating process at temperatures higher than or equal to 1000° C.

If the heating process is performed at such high temperatures, there occurs a problem that one of the plane orientations breaks the other plane orientation due to silicon-to-silicon contact under the PFET region, that is, on the interface between the (110)/(100) layers of different plane orientations and crystal defects occur.

### BRIEF SUMMARY OF THE INVENTION

According to a first aspect of the present invention, there is provided a direct bond substrate which includes a first semiconductor substrate, a film which is formed on the first semiconductor substrate and includes one of a nitride film, oxynitride film, carbide film and an oxide film containing carbon, and a second semiconductor substrate bonded to the first semiconductor substrate with the film disposed therebetween.

According to a second aspect of the present invention, there is provided a semiconductor device which includes a semiconductor substrate, a film which is formed on a main surface of the semiconductor substrate and includes one of a nitride film, oxynitride film, carbide film and an oxide film containing carbon, a first semiconductor layer formed on a first region of the film and having a plane orientation different from that of the main surface of the semiconductor substrate, a second semiconductor layer formed on a portion of the main surface of the semiconductor substrate on which the first semiconductor layer is not formed, the second semiconductor layer having a plane orientation which is the same as that of the main surface of the semiconductor substrate, FETs of a first conductivity type formed in the first semiconductor layer, and FETs of a second conductivity type formed in the second semiconductor layer.

According to a third aspect of the present invention, there is provided a manufacturing method of a semiconductor device which includes subjecting a main surface of a first semiconductor substrate to one of a nitridation process and carbonization process, and bonding a second semiconductor substrate to the main surface of the first semiconductor substrate.

### BRIEF DESCRIPTION OF THE SEVERAL VIEWS OF THE DRAWING

FIG. 1 is a cross-sectional view showing one manufacturing step of a direct bond substrate according to a first embodiment of this invention;

FIG. 2 is a cross-sectional view showing one manufacturing step following after the step of FIG. 1 of the direct bond substrate;

FIG. 3 is a cross-sectional view showing one manufacturing step following after the step of FIG. 2 of the direct bond substrate;

FIG. 4 is a cross-sectional view showing one manufacturing step of a semiconductor device using the direct bond substrate which follows after the step of FIG. 3;

FIG. 5 is a cross-sectional view showing one manufacturing step of the semiconductor device using the direct bond substrate which follows after the step of FIG. 4;

FIG. 6 is a cross-sectional view showing one manufacturing step of the semiconductor device using the direct bond substrate which follows after the step of FIG. 5;

FIG. 7 is a cross-sectional view showing one manufacturing step of the semiconductor device using the direct bond substrate which follows after the step of FIG. 6;

FIG. 8 is a cross-sectional view showing one manufacturing step extracted for illustrating a direct bond substrate according to a second embodiment of this invention, a semiconductor device using the direct bond substrate and a manufacturing method thereof;

FIG. 9 is a cross-sectional view showing one manufacturing step, for illustrating a manufacturing method of a direct bond substrate according to a third embodiment of this invention;

FIG. 10 is a cross-sectional view showing a step following after the step of FIG. 9, for illustrating the manufacturing method of the direct bond substrate;

FIG. 11 is a cross-sectional view showing a step following after the step of FIG. 10, for illustrating the manufacturing method of the direct bond substrate; and

FIG. 12 is a cross-sectional view showing a step following after the step of FIG. 11, for illustrating the manufacturing method of the direct bond substrate.

### DETAILED DESCRIPTION OF THE INVENTION

### First Embodiment

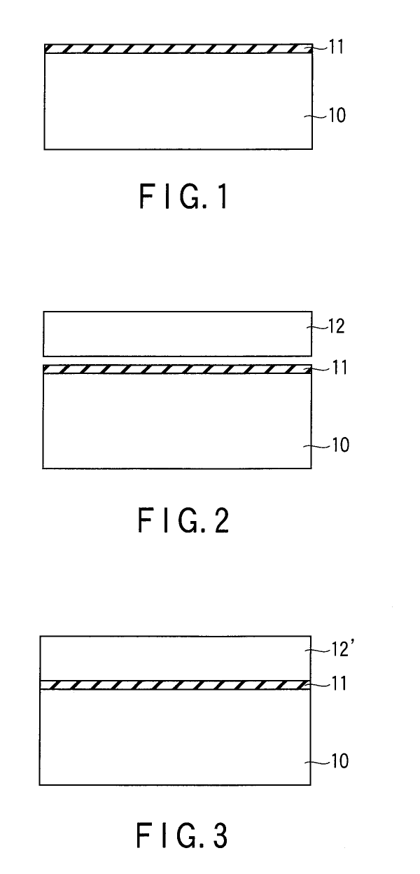

A manufacturing method of a direct bond substrate according to a first embodiment of this invention, in this example, a direct silicon bond substrate and a semiconductor device using the DSB substrate is explained with reference to FIGS. 1 to 7. In the present embodiment, a nitride film or oxynitride film is provided on the bonded interface of the DSB substrate formed by bonding silicon substrates together.

First, as shown in FIG. 1, a silicon nitride film or silicon oxynitride film 11 is formed on the surface of a (100) silicon substrate 10 used as a base substrate.

For example, a natural oxide film (not shown) on the surface of the silicon substrate 10 is subjected to a nitridation process by placing the silicon substrate 10 in a state of the temperature of 650° C. and the pressure of approximately 10 Torr for approximately 30 minutes in an NH₃ atmosphere. As a result, a silicon nitride film or silicon oxynitride film 11 containing nitrogen with a surface density of 1×10¹⁴ atoms/cm² or more, for example, 1×10¹⁵ atoms/cm² can be formed.

In this case, whether or not a pure silicon nitride film is formed as the silicon nitride film or silicon oxynitride film 11 or whether the film is formed on or under the natural oxide film is determined depending on the manufacturing method.

A nitridation material used in the nitridation process, for example, NH₃ not only nitrides the surface of the natural oxide film but also mostly passes through the natural oxide film and reaches the interface with the silicon substrate 10 to react with Si of the interface with the silicon substrate 10 and form SiN. Therefore, most of the silicon nitride film is formed under the natural oxide film, that is, on the surface of the silicon substrate 10.

At this time, if NH₃ plasma or the like that is highly reactive is used, a nitridation process that improves the film quality, for example, that replaces oxygen of the natural oxide film by nitrogen is performed.

Further, if a deposition method such as a chemical vapor deposition (CVD) method or atomic layer deposition (ALD) method is used, a silicon nitride film is formed on the natural oxide film.

However, in the present embodiment, there occurs no problem even if the silicon nitride film is formed on or under the natural oxide film or if nitrogen is introduced into the natural oxide film to form so-called SiOxNy.

The film thickness of the silicon nitride film or silicon oxynitride film 11 formed as described above is approximately 2 nm at most.

A silicon substrate having a plane orientation different from that of the base substrate 10, for example, a (110) silicon substrate 12 is bonded to the surface of the base substrate 10 on which the silicon nitride film or silicon oxynitride film 11 is formed with the surface of the plane orientation set to face the surface of the base substrate 10 as shown in FIG. 2. A thermocompression bonding process or the like performed to form a bond SOI substrate can be used as the bonding process.

After this, a DSB substrate having a thin silicon film 12′ of the (110) plane orientation mounted on the (100) silicon substrate 10 with the silicon nitride film or silicon oxynitride film 11 disposed therebetween is completed by separating the (110) silicon substrate 12 and leaving behind only a layer of several ten nm to several hundred nm lying near the surface portion of the bonded surface of the (110) silicon substrate 12 (FIG. 3).

The silicon nitride film or silicon oxynitride film 11 is disposed on the interface between the (110)/(100) layers of the DSB substrate formed as described above.

The separating process performed after the bonding process can be performed by previously implanting hydrogen atoms into a portion of several ten nm to several hundred nm from the bonded surface of the (110) silicon substrate 12 before the bonding process, for example. That is, a “gap portion” whose coupling strength is weakened is previously formed in a portion of several ten nm to several hundred nm from the bonded surface of the (110) silicon substrate 12. In FIG. 3, the separating process is not shown for brevity of the drawing and the process is shown by expressing the (110) silicon film 12′ thin.

Next, a process of manufacturing a semiconductor device having a HOT structure by use of the DSB substrate shown in FIG. 3 is explained below.

In the case of the present embodiment, the (100) silicon substrate 10 is used as a base substrate acting as a ground layer. Therefore, an opening is formed in a region in which NFETs are to be formed while a region in which PFETs are to be formed is left behind after the substrate surface is covered with an adequate mask material 13 (for example, a thin film such as a silicon nitride film or silicon oxide film by a CVD process or photoresist film).

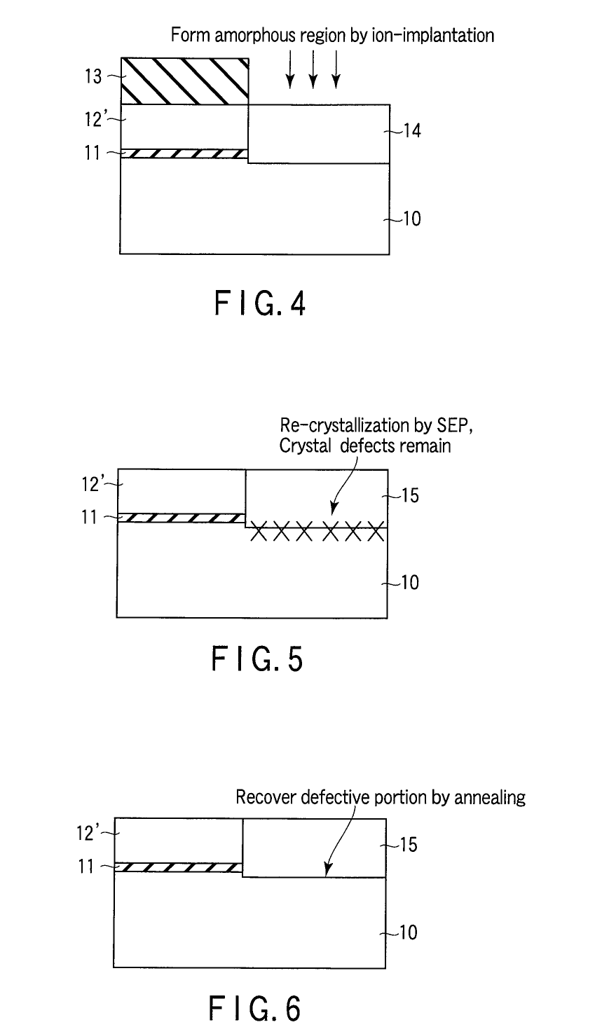

As shown in FIG. 4, ions of the group IV such as Si, Ge or ions of inert gas such as Ar are ion-implanted into the region in which the NFETs are to be formed from above the resultant structure by using an ion-implantation apparatus. The ion-implantation process is performed with such energy and dose amount as to form the (110) silicon film 12′ on the substrate surface and part of the upper surface portion of the (100) silicon substrate 10 that lies below the above silicon film into an amorphous form. Thus, a portion ranging from the surface of the above region to part of the upper surface of the (100) silicon substrate 10 is formed into an amorphous form and an amorphous silicon (a-Si) layer 14 is formed.

After this, the portion (a-Si layer) 14 that is formed into the amorphous form by solid phase epitaxy as shown in FIG. 5 is re-crystallized by performing an annealing process at temperatures higher than or equal to 600° C. At this time, in order to acquire information of re-crystallization from the underlying (100) silicon substrate 10, a portion 15 that is once formed into an amorphous form and re-crystallized is formed to have a (100) plane orientation in a region to the surface.

By the above process, the (110) silicon film 12′ (first semiconductor layer) and the re-crystallized portion 15 with the (100) plane orientation (second semiconductor layer) are respectively formed in the PFET forming region and NFET forming region and thus a HOT structure having different plane orientations can be formed.

Damage of crystals destroyed by the ion-implantation process still remain as crystal defects even after the NFET region is recovered from the amorphous state and re-crystallized by solid phase epitaxy. Thus, as shown in FIG. 6, in order to recover the region from the crystal defects, an annealing process is performed at temperatures higher than or equal to 1000° C.

At this time, a natural oxide film (silicon oxide film with the film thickness of several nm) disposed on the interface between the (110)/(100) layers acts as a factor that causes crystal defects in the conventional DSB substrate formed by a general manufacturing method. That is, a silicon oxide film that is a natural oxide film naturally formed when silicon substrates are bonded together functions as a protection film between the different silicon substrates. However, the silicon oxide film contracts as the annealing temperature becomes higher, and it tends to adopt a spherical formation due to surface tension. As a result, finally, a silicon-to-silicon contact cannot be prevented and crystal defects will occur.

In the present embodiment, the silicon nitride film or silicon oxynitride film 11 disposed on the (110)/(100) interface has higher heat resistance in comparison with the natural oxide film and will not be broken in the high-temperature process.

Therefore, preferable crystal structures can be maintained in the respective regions in which PFETs and NFETs are to be formed without causing crystal defects on the (110)/(100) interface even if the annealing process is performed. That is, according to the present embodiment, the annealing process can be performed at temperatures higher than or equal to 1000° C. and damage of crystals destroyed by the ion-implantation process can be effectively recovered.

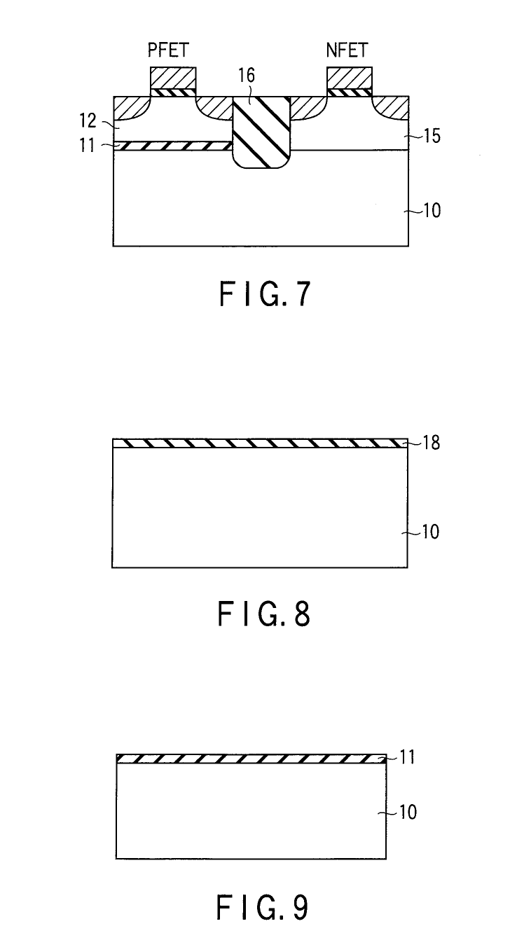

After this, as shown in FIG. 7, an STI region 16 is formed on the main surface (element forming surface) of the DSB substrate by a known process, a PFET (FET of a first conductivity type) and an NFET (FET of a second conductivity type) are respectively formed on the (110) silicon film 12′ and the portion 15 re-crystallized with the (100) plane orientation. It is known that the mobility of holes that are carriers of the PFET is high in the (110) substrate and the mobility of electrons that are carriers of the NFET is high in the (100) substrate. Therefore, the respective carrier mobilities can be enhanced by causing the regions in which the PFET and NFET are formed to have adequate plane orientations of the substrate and the operation speed of an LSI can be enhanced by increasing currents flowing through the current paths of the FETs (MOSFETs).

Further, as the heating process in a normal LSI manufacturing process, a large number of heating processes are provided that include not only the annealing process performed to eliminate defects in the HOT structure but also an activation annealing process performed to highly activate impurities implanted into the source and drain of the MOSFET and alleviate stress of a silicon oxide film used as a burying material in the STI region.

The interface containing nitrogen and formed in the present embodiment can prevent the film from being broken due to the high heat resistance in the above processes and maintain a preferable crystal state. In this case, it is possible to attain a sufficient effect if the ratio of nitrogen in a silicon oxynitride film formed on the interface is set to approximately 2 to 3%. However, if a nitride amount becomes large, the nitrogen concentration becomes excessively high or the film thickness of the oxynitride film becomes excessively large, silicon substrates cannot be directly bonded together and are electrically isolated from each other. However, if the concentration lies in the range of approximately 1×10₄₄ atoms/cm² to 1×10¹⁵ atoms/cm², the electrically conductive state can be maintained. The heat resistance and the electrical conductivity are set in a trade-off relation, and if the oxygen concentration in the oxynitride film is kept constant, the heat resistance becomes higher but the conductivity becomes lower as the nitrogen concentration increases.

As explained above, a preferable crystal state can be maintained in various heating processes in the LSI manufacturing process by using the manufacturing method of the DSB substrate according to the present embodiment. As a result, a semiconductor device having fewer defects such as poor contacts can be formed. Further, since the interface with high heat resistance is formed by use of an oxide film containing nitrogen, breakage caused by the heating process can be prevented and it becomes possible to attain an advantage that the restriction such as the highest temperature at the time of forming a semiconductor device can be alleviated.

### Second Embodiment

A manufacturing method of a direct bond substrate according to a second embodiment of this invention is explained with reference to FIG. 8. In the present embodiment, a carbide film or oxide film containing carbon is provided on the bonded interface of the DSB substrate.

First, as shown in FIG. 8, a silicon carbide film or a silicon oxide film 18 containing carbon is formed on the surface of a (100) silicon substrate 10 used as a base substrate.

Next, for example, a natural oxide film on the surface of the silicon substrate is subjected to a carbonization process by placing the silicon substrate 10 in a state of a temperature of 900° C. or more and a pressure of approximately 10 Torr for approximately 30 minutes in an ethylene (C₂H₄) atmosphere. As a result, a silicon carbide film or a silicon oxide film 18 containing carbon with a surface density of 1×10¹⁴ atoms/cm² to 1×10¹⁵ atoms/cm² can be formed.

In this case, like the case of formation of the silicon nitride film in the first embodiment, whether or not a pure silicon carbide film is formed as the silicon carbide film or silicon oxide film 18 containing carbon or whether the film is formed on or under the natural oxide film is determined depending on the manufacturing method.

The film thickness of the silicon carbide film or silicon oxide film 18 containing carbon formed as described above is approximately 2 nm at most.

The process performed after this is the same as the process in the first embodiment.

The heat resistance of the silicon carbide film is further enhanced in comparison with that of the silicon nitride film and the silicon carbide film is excellent in conductivity. Therefore, the heat resistance can be further enhanced and the conductivity can be maintained high by using a thin film of a silicon oxide film containing carbon or a silicon carbide film containing carbon with a surface density of 1×10¹⁴ atoms/cm² or more.

As described above, in the present embodiment, not only a silicon oxide material but also a silicon nitride material or carbide material having a high melting point is provided on the interface by introducing nitrogen or carbon into the bonded interface of the DSB substrate. Thus, the heat resistance of the interface is enhanced and a direct bond substrate structure having different plane orientations can be maintained even if the high-temperature heating process is performed.

(Modifications of First and Second Embodiments)

In the first and second embodiments, a case wherein the DSB substrate formed by bonding the silicon substrate to the silicon substrate whose plane orientation is different from that of the above silicon substrate is taken as an example is explained. However, if a germanium (Ge) substrate is bonded to the silicon substrate, the same effect can be attained.

Since silicon and germanium have different lattice constants, a problem of occurrence of crystal defects in the heating process similarly occurs when the substrates are bonded together by use of a conventional general DSB manufacturing method irrespective whether the plane orientations are the same or different. On the other hand, like the case of the first and second embodiments, occurrence of crystal defects can be prevented by forming a nitride film, oxynitride film, carbide film or oxide film containing carbon on the bonded interface.

### Third Embodiment

A direct bond substrate according to a third embodiment of this invention and a manufacturing method thereof are explained with reference to FIGS. 9 to 12. In the present embodiment, a (100) germanium substrate is bonded on a (100) silicon substrate and a (110) silicon substrate is further bonded on the resultant structure.

First, as shown in FIG. 9, a silicon nitride film or silicon oxynitride film 11 is formed on the surface of the (100) silicon substrate 10 used as a base substrate.

For example, a natural oxide film (not shown) on the surface of the silicon substrate 10 is subjected to a nitridation process by placing the silicon substrate 10 in a state of a temperature of 650° C. and pressure of approximately 10 Torr for approximately 30 minutes in an NH₃ atmosphere. As a result, a silicon nitride film or silicon oxynitride film 11 containing nitrogen with a surface density of 1×10¹⁵ atoms/cm² can be formed, for example.

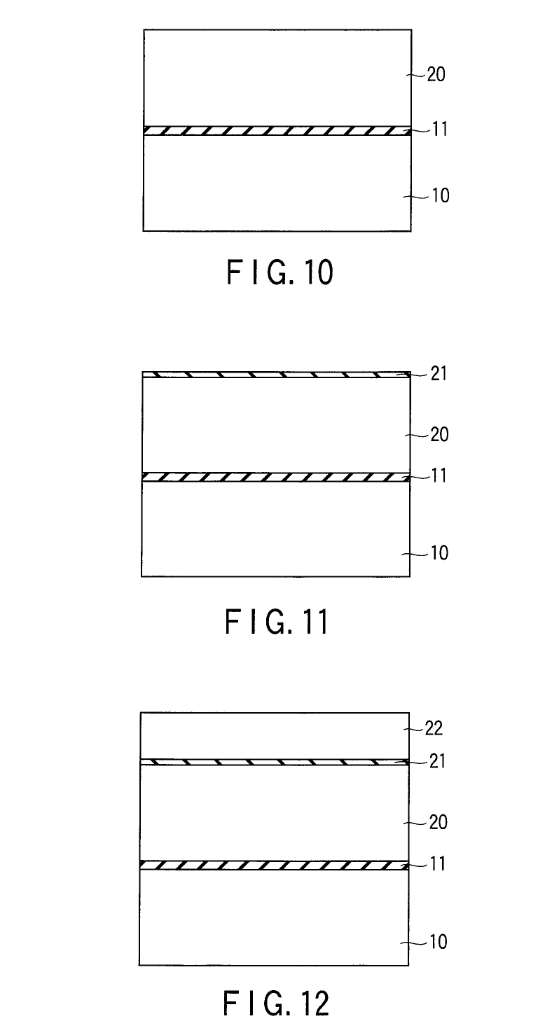

Next, as shown in FIG. 10, a (100) germanium substrate is attached to the base body to form a germanium layer 20 with a desired film thickness of 300 nm, for example. Further, as shown in FIG. 11, a thin silicon nitride film (SiN) 21 is deposited and formed to a thickness of 1 nm on the surface of the germanium layer 20 by use of an ALD (Atomic Layer Deposition) method.

As shown in FIG. 12, a (110) silicon substrate is further attached to the resultant semiconductor structure and processed to a desired thickness of 100 nm, for example, to form a silicon layer 22.

The silicon nitride film or silicon oxynitride film 11 formed by an oxynitridation process is provided on the Si(100)/Ge(100) interface of the direct bond substrate formed by performing the above processes and the deposited silicon nitride film 21 formed by the ALD method is provided on the Ge(100)/Si(110) interface.

The heat resistance of the above silicon nitride films is higher than that of the silicon oxide film and the silicon nitride film is not broken in the high-temperature process. Therefore, preferable crystal states can be maintained in the respective regions in which PFETs and NFETs are formed without causing crystal defects to occur from the interface in which silicon and germanium having different plane orientations on the Ge(100)/Si(100) interface are brought into contact with each other.

Further, since diffusion of Ge from the germanium layer 20 to the silicon layer 10 and silicon layer 22 and diffusion of Si from the silicon substrate 10 and silicon layer 22 lying on both sides to the germanium layer 20 can be prevented, Si and Ge can be prevented from being mixed together in the heating process.

Further, the (110) silicon layer 22 on the surface of a DSB wafer with the above structure is formed into an amorphous form by a pre-amorphization (PAI) process and then re-crystallized. As a result, Si with a plane orientation (100) can be arranged solely in the region subjected to PAI and so-called strained silicon in which crystals are strained due to the difference between the lattice distances of Si and underlying Ge can be formed. By using the above region as a channel region of the MOSFET, the carrier mobility can be enhanced to enhance the performance of the MOSFET.

As the heating process in a normal LSI manufacturing process, not only is the annealing process performed to eliminate defects in the HOT structure described above provided but also a large number of other heating processes are provided. The interface containing nitrogen and formed in the present embodiment can prevent breakage of the film due to the excellent heat resistance in the above processes and maintain the preferable crystal state.

Further, as the Ge layer forming method, it is possible to form a Ge layer on the (100) silicon substrate used as a base substrate not by bond as described above but by epitaxial growth. When the Ge layer is formed on silicon by epitaxial growth, it is preferable to epitaxially grow SiGe having a lattice constant between those of silicon and germanium as a buffer layer and form a Ge layer thereon by epitaxial growth in order to eliminate mismatching in the size of crystal defects of silicon and germanium.

In this case, it is impossible to dispose a silicon nitride film or silicon oxynitride film on the interface between the (100) Si substrate 10 and the SiGe layer used as a buffer and the Ge layer 20. However, a silicon nitride film can be disposed on the interface on which the Ge layer 20 and (110) Si layer 22 are bonded together by use of the above method.

As described above, according to one aspect of this invention, a direct bond substrate that can maintain a preferable crystal state even in various heating processes in the LSI manufacturing process, a semiconductor device using the above substrate and a manufacturing method thereof can be obtained.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A direct bond substrate comprising:
a first semiconductor substrate,
a film formed on the first semiconductor substrate, the film including one of a nitride film, oxynitride film, carbide film and an oxide film containing carbon, and
a second semiconductor substrate bonded to the first semiconductor substrate with the film disposed therebetween.

2. The direct bond substrate according to claim 1, wherein surface portions of the first and second semiconductor substrates which are bonded together with the film disposed therebetween have different plane orientations.

3. The direct bond substrate according to claim 1, wherein the first semiconductor substrate is a silicon substrate and one of the nitride film and oxynitride film is one of a silicon nitride film and silicon oxynitride film which contains nitrogen with a surface density of 1×10¹⁴ atoms/cm² to 1×10¹⁵ atoms/cm².

4. The direct bond substrate according to claim 1, wherein the first semiconductor substrate is a silicon substrate and one of the carbide film and the oxide film containing carbon is one of a silicon carbide film and a silicon oxide film containing carbon which contains carbon with a surface density of 1×10¹⁴ atoms/cm² to 1×10¹⁵ atoms/cm².

5. The direct bond substrate according to claim 1, further comprising one of a nitride film and oxynitride film formed on the second semiconductor substrate and a third semiconductor substrate formed on the one of the nitride film and oxynitride film.

6. The direct bond substrate according to claim 5, wherein surface portions of the first and second semiconductor substrates which are bonded together with the film disposed therebetween have the same plane orientation and a surface of the third semiconductor substrate bonded with one of the nitride film and oxynitride film disposed therebetween has a plane orientation different from that of the second semiconductor substrate.

7. The direct bond substrate according to claim 6, wherein the first and third semiconductor substrates are silicon substrates and the second semiconductor substrate is a germanium substrate.

8. A semiconductor device comprising:
a first semiconductor substrate,
a film which is formed on a first region on a main surface of the first semiconductor substrate, the film including one of a nitride film, oxynitride film, carbide film and an oxide film containing carbon,
a first semiconductor layer formed on the film, the first semiconductor layer having a plane orientation different from that of the main surface of the first semiconductor substrate,
a second semiconductor layer formed on the third region on the main surface of the first semiconductor substrate, the second semiconductor layer having a plane orientation which is the same as that of the main surface of the first semiconductor substrate,
FETs of a first conductivity type formed in the first semiconductor layer, and
FETs of a second conductivity type formed in the second semiconductor layer.

9. The semiconductor device according to claim 8, wherein the first semiconductor layer is formed by separating a second semiconductor substrate having a plane orientation different from that of the first semiconductor substrate after the second semiconductor substrate is bonded on the surface of the film and leaving behind a portion which lies near a bonded interface.

10. The semiconductor device according to claim 8, wherein the second semiconductor layer is formed by re-crystallizing a layer obtained by forming part of the upper surface of the first semiconductor substrate and the first semiconductor layer into an amorphous form.

11. A manufacturing method of a semiconductor device comprising:
subjecting a main surface of a first semiconductor substrate to one of a nitridation process and carbonization process, and
bonding a second semiconductor substrate to the main surface of the first semiconductor substrate.

12. The manufacturing method of a semiconductor device according to claim 11, wherein the nitridation process is to nitride a natural oxide film formed on the surface of the first semiconductor substrate.

13. The manufacturing method of a semiconductor device according to claim 12, wherein one of a silicon nitride film and silicon oxynitride film which contains nitrogen with a surface density of 1×10¹⁴ atoms/cm² to 1×10¹⁵ atoms/cm² is formed by nitridation the natural oxide film.

14. The manufacturing method of a semiconductor device according to claim 11, wherein the carbonization process is to carbonize a natural oxide film formed on the surface of the first semiconductor substrate.

15. The manufacturing method of a semiconductor device according to claim 14, wherein one of a silicon carbide film and a silicon oxide film which contains carbon with a surface density of 1×10¹⁴ atoms/cm² to 1×10¹⁵ atoms/cm² is formed by carbonization the natural oxide film.

16. The manufacturing method of a semiconductor device according to claim 11, wherein surface portions of the first and second semiconductor substrates which are bonded together have different plane orientations.

17. The manufacturing method of a semiconductor device according to claim 11, further comprising depositing and forming a silicon nitride film on a main surface of the second semiconductor substrate, and bonding a third semiconductor substrate on the silicon nitride film.

18. The manufacturing method of a semiconductor device according to claim 17, wherein surface portions of the first and second semiconductor substrates which are bonded together have the same plane orientation and a bonded surface portion of the third semiconductor substrate has a plane orientation different from that of the second semiconductor substrate.

19. The manufacturing method of a semiconductor device according to claim 11, further comprising separating the second semiconductor substrate after the bonding the second semiconductor substrate and then leaving behind a portion which lies near a bonded interface to form a semiconductor layer.

20. The manufacturing method of a semiconductor device according to claim 19, further comprising implanting ions with energy and dose amount to form part of an upper surface of the first semiconductor substrate into an amorphous form with a first region on the semiconductor layer used as a mask after the forming the semiconductor layer, forming a second region by re-crystallizing a layer which is formed into an amorphous form by annealing, and respectively forming PFETs and NFETs in the first and second regions.
